(19) United States
(12) Patent Application Publication
(10) Pub. No.: US 2006/0226123 A1
(43) Pub. Date: Oct. 12, 2006

(54) Profile control using selective heating

(75) Inventor: Manoocher Birang, Los Gatos, CA (US)

Correspondence Address: FISH & RICHARDSON P.C., P.O. BOX 1022, MINNEAPOLIS, MN, 55440-1022, US

(73) Assignee: Applied Materials, Inc.

(21) Appl. No.: 11/101,106

(22) Filed: Apr. 7, 2005

(51) Int. Cl. C03C 15/00; C23F 1/00; B44C 1/22; H01L 21/461

(52) U.S. Cl. 216/88; 438/692; 216/84; 156/345.12; 156/345.13

(57) ABSTRACT

A semiconductor processing system includes a thickness monitoring system, a position monitoring system, and a processor. The processor is configured to receive information indicative of a local thickness of a layer on a substrate during processing, and information indicative of a position of the substrate during processing. The system may include an energy source to receive parameters from the processor, and to selectively output energy based on the parameters. The information indicative of a local thickness of a layer on a substrate may be indicative of a radial thickness distribution.

### TECHNICAL FIELD

This invention relates to semiconductor processing, and more particularly to process variability reduction.

### BACKGROUND

An integrated circuit is typically formed on a substrate (e.g. a semiconductor wafer) by the sequential deposition of conductive, semiconductive or insulative layers on a silicon wafer, and by the subsequent processing of the layers.

One fabrication step involves depositing a filler layer over a non-planar surface, and planarizing the filler layer until the non-planar surface is exposed. For example, a conductive filler layer can be deposited on a patterned insulative layer to fill the trenches or holes in the insulative layer. The filler layer is then polished until the raised pattern of the insulative layer is exposed. After planarization, the portions of the conductive layer remaining between the raised pattern of the insulative layer form vias, plugs and lines that provide conductive paths between thin film circuits on the substrate. In addition, planarization may be used to planarize the substrate surface for lithography.

Chemical mechanical polishing (CMP) is one accepted method of planarization. This planarization method typically requires that the substrate be mounted on a carrier or polishing head. The exposed surface of the substrate is placed against a rotating polishing disk pad or belt pad. The polishing pad can be either a “standard” pad or a fixed-abrasive pad. A standard pad has a durable roughened surface, whereas a fixed-abrasive pad has abrasive particles held in a containment media. The carrier head provides a controllable load on the substrate to push it against the polishing pad. A polishing slurry, including at least one chemically-reactive agent, and abrasive particles if a standard pad is used, is supplied to the surface of the polishing pad.

### SUMMARY

In general, in one aspect, a method of chemical mechanical polishing includes polishing a substrate using a polishing apparatus and generating one or more signals indicative of a thickness of a plurality of conductive regions of the substrate during polishing. The method may also include determining one or more control parameters for an energy source in communication with at least a portion of the polishing apparatus based on the one or more signals indicative of the thickness of the plurality of conductive regions. The method may also include and controlling the energy source based on the one or more control parameters.

The energy source may be a thermal radiative source; for example, one or more heaters. The heaters may be arranged radially. The heaters may be in thermal communication with a substrate during polishing. For example, the heaters may selectively heat portions of the polishing pad, a membrane in a substrate support structure, and/or other parts of the chemical mechanical polishing system that are in thermal communication with the substrate during polishing. Some or all of the acts may be implemented using an article comprising one or more storage media having stored thereon executable instructions.

In general, in another aspect, a method of semiconductor processing includes during processing, receiving information indicative of a thickness of a layer on a substrate and receiving information indicative of an associated location for the information indicative of the thickness on the substrate. The method may further include determining one or more control parameters for an energy source based on the information indicative of the thickness and the information indicative of an associated location. The method may further include, during processing, controlling the energy source using the control parameters. Some or all of the acts may be implemented using an article comprising one or more storage media having stored thereon executable instructions.

In general, in another aspect, a semiconductor processing system includes a thickness monitoring system configured to output information indicative of a local thickness of a layer on a substrate during processing. The system may also include a position monitoring system configured to output information indicative of a position of the substrate during processing. The system may also include a processor to receive the information indicative of the local thickness and the information indicative of the position and to determine one or more parameters based thereon, the processor further configured to output the one or more parameters.

The details of one or more implementations are set forth in the accompanying drawings and the description below. Other features and advantages will be apparent from the description and drawings, and from the claims.

### DESCRIPTION OF DRAWINGS

FIG. 1 is an implementation of a system to control an energy source based on thickness information.

FIGS. 2A and 2B show side and top view of an implementation of a chemical mechanical polishing system.

FIG. 2C shows a side view of a different implementation of a chemical mechanical polishing system.

FIG. 3 shows a chemical mechanical polishing system that may include a system such as that shown in FIGS. 2A-2C.

FIGS. 4A and 4B show implementations of eddy current monitoring systems.

FIG. 5 shows a different implementation of an eddy current monitoring system.

FIG. 6 shows a method to reduce non-uniformity using thickness information to control an energy source.

Like reference symbols in the various drawings indicate like elements.

### DETAILED DESCRIPTION

In semiconductor processing, process control can be important in ensuring that devices being fabricated function as intended. Process control is used to decrease variability and thus improve uniformity for particular substrates (cross-wafer uniformity), as well as between different substrates (wafer-to-wafer uniformity).

One substrate property that may be measured and controlled is the thickness of one or more particular layers on a substrate. For example, in a CMP process, the thickness of a layer may be monitored during polishing to determine whether the polishing is occurring uniformly across the surface of the wafer. Non-uniform polishing may lead to undesired results; for example, a metal layer may be fully removed from some regions of the wafer but not others.

Environmental factors may affect semiconductor processing, and differences in these factors across particular wafers and/or between different wafers may lead to non-uniformities. Temperature is one environmental factor that may affect processing. For example, in a chemical mechanical polishing process, chemical and/or electrochemical processing reaction rates may depend on the local temperature. For some polishing chemistries, regions at higher temperatures may polish more quickly than regions at lower temperatures. For other polishing chemistries, regions at higher temperatures may polish more slowly than regions at lower temperatures.

In order to reduce non-uniformity due to variation of environmental factors such as temperature, some existing systems monitor the environmental factors, then use feedback techniques to try to improve the uniformity of the environmental factors. For example, some existing systems try to maintain a constant temperature during processing, using measured temperature as a feedback parameter.

In contrast, implementations described herein provide for process control using thickness information as a feedback parameter for controlling one or more environmental factors using an energy source. By doing so, the systems and techniques described herein provide for reliable process monitoring, but without requiring additional sensors to detect parameters directly related to environmental factors (e.g., without thermometers).

Additionally, using measured thickness information as a feedback parameter for an energy source may enable reduction of non-uniformity due to other factors. In a CMP system (for example), if the pressure applied across a wafer during polishing is non-uniform, the thickness profile may be non-uniform. One way to reduce this non-uniformity is to modify the pressure profile during polishing. Another way is to control an energy source so that polishing rates in relatively under-polished regions are increased with respect to polishing rates in relatively over-polished regions. In some circumstances, multiple control techniques may be used together (e.g., controlling the pressure to reduce non-uniformities as well as controlling an energy source to selectively modify reaction rates).

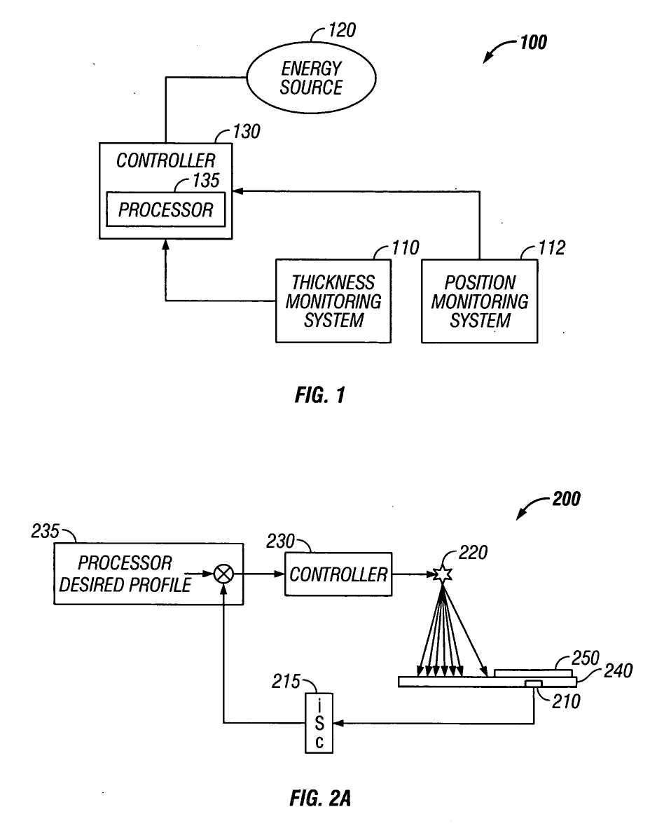

FIG. 1 shows an implementation of a system 100 that may be used to improve uniformity using thickness information as a feedback parameter. A thickness monitoring system 110 is in communication with a semiconductor processing system. Thickness monitoring system 110 generates thickness information for different regions on substrates being processed, during processing. Thickness information obtained during processing may be referred to as a measured in-situ thickness profile.

A controller 130 is configured to receive thickness information from thickness monitoring system 110. Controller 130 includes a processor 135 that determines control parameter information based on the thickness information. For example, processor 135 may compare the measured in-situ thickness profile with one or more reference profiles to determine whether any control parameters may need to be updated to improve cross-wafer thickness uniformity. If so, controller 130 may provide updated control information to an energy source 120. Controller 130 may receive information from other parts of system 100. For example, controller 130 may receive position information from (for example) a position monitoring system 112 which may include an optical interrupter and/or encoder.

Energy source 120 is configured to selectively provide a non-uniform energy distribution to a processing system. For example, energy source 120 may be a heat source such as a radiative heat source configured to selectively heat regions of the processing system by different amounts. In an implementation of a chemical mechanical polishing system, a radiative heat source may heat different regions of a polishing pad differently, so that regions of the polishing pad that are at a higher temperature polish at a higher rate than regions of the polishing pad that are at a lower temperature.

In one implementation, the energy source 120 can include multiple independently controllable radiative heaters, e.g., heat lamps, each positioned to heat a different portion of the polishing pad. For example, the multiple radiative heaters can be positioned along a radius of the polishing pad.

In another implementation, the energy source 120 can include a single radiative heater that is movable across the polishing pad surface, e.g., along a radius of the polishing pad. In this implementation, at a different radial regions of the polishing pad are heated to different temperatures by controlling the intensity (or pulse width) of the energy source as it moves over the polishing pad surface.

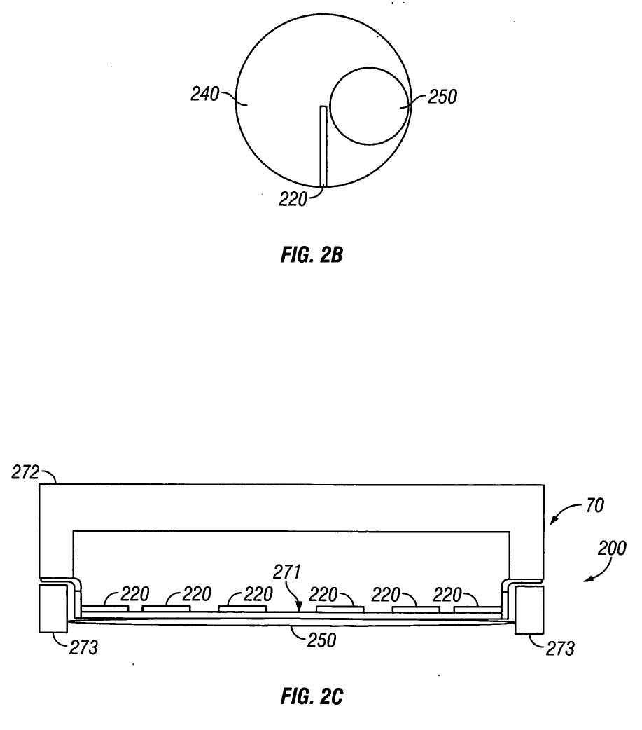

FIGS. 2A and 2B show side and top views of an implementation of a chemical mechanical polishing system 200. Chemical mechanical polishing generally refers to systems and techniques used to remove material across a surface of a wafer, in order to generally planarize the surface. In some chemical mechanical polishing systems, a rotating polishing pad with an abrasive slurry is brought into contact with the surface of a rotating wafer. In other chemical mechanical polishing systems, a belt configuration is used rather than a rotating polishing pad.

The chemicals and materials used may also vary. For example, the slurry used in an oxide polishing process may be basic, while the slurry used in a metal polishing process may be acidic. In another example, chemical mechanical polishing system may use a de-plating solution, as well as an applied potential difference between an electrode in electrical communication with the de-plating solution and an electrode in communication with a layer to be polished (for example, a copper layer). This may alternatively be referred to as electrochemical mechanical polishing.

Chemical and electrochemical interactions that may occur during chemical mechanical polishing may occur at different rates depending on environmental characteristics. For example, chemical mechanical polishing rates may be greater in regions of higher temperature than of lower temperature.

The systems and techniques described here may be particularly effective for metal CMP. In metal CMP, a relatively larger amount of material is removed by chemical reaction than by physical (e.g., abrasive) action compared with oxide CMP. Since reaction rates are increased by increasing the temperature, selective heating of the polishing system (e.g., of the polishing pad) may selectively increase the metal removal rate to a greater extent than with oxide polishing.

Referring again to FIGS. 2A and 2B, system 200 includes a wafer 250 to be polished using a polishing pad 240. During polishing, a thickness monitoring system 210 may be used to detect a signal indicative of thickness of one or more layers on wafer 250. For example, system 210 may be an eddy current monitoring system. In an eddy current monitoring system, time-dependent magnetic fields are generated. These magnetic fields in turn generate eddy currents in conductive regions in electromagnetic communication with the magnetic fields. Signals indicative of generated eddy currents, which generally vary with the thickness of conductive regions on the wafer, may then be detected.

Signals from thickness monitoring system 210 may be provided to a processing system 215. Processing system 215 may convert analog signals from system 210 to digital information. The digital information may include information indicative of a position (or a region) on wafer 250 as well as associated thickness information for the position. System 215 may output an in-situ measured thickness profile for wafer 250 during chemical mechanical polishing.

The in-situ measured thickness profile may be compared to a target profile using a processor 235. Processor 235 may then determine whether control parameters need to be updated. If so, processor 235 may provide control parameters to a controller 230 in communication with radiative heater 220. In some implementations, heater 220 may be a pulse width modulated heater. That is, the heat intensity may be controlled by modulating the width of a pulse, where a longer resident time in a particular region (e.g., a particular radial extent of wafer 250) provides for more heat to the particular region and a higher accumulated temperature.

As shown in FIGS. 2A and 2B, heater 220 heats polishing pad 240 from the wafer side. The current inventors realized that by doing so, thermal energy may be more effectively coupled to the polishing pad than if heater 220 were to heat polishing pad 240 from the platen side. This is due to the relatively large thermal mass of the platen and to the thermal resistance of polishing pad 240.

As shown in FIG. 2B, heater 220 may selectively heat polishing pad 240 radially. For such an implementation, system 210 generates signals indicative of thickness of a conductive region as the eddy current probe of system 210 sweeps across a region of wafer 250. The signals are then converted to thickness-related data. The thickness-related data is processed (e.g., executing program steps on a computer) to determine areas of wafer 250 that are being polished relatively more slowly. The program may use the geometric relationship between the wafer, pad, and sweep motions to determine which radial sections of the pad to heat in order to increase the polish rate at a corresponding wafer radius, and to determine corresponding pulse widths for heater 220.

Other heater configurations may be used. For example, FIG. 2C shows a different implementation of a chemical mechanical polishing system 200. System 200 includes a carrier head 70 with a membrane 271, housing 272, and retaining ring 273. In FIG. 2C, one or more heaters 220 may be used to heat part of a substrate backing system such as membrane 271, in addition to or instead of the polishing pad and/or other parts of chemical mechanical polishing system 200. Many different carrier head designs may be used; for example, carrier heads as shown and described in U.S. patent application Ser. No. 10/806,649, entitled CARRIER HEAD WITH FLEXIBLE MEMBRANE TO PROVIDE CONTROLLABLE PRESSURE AND LOADING AREA, filed Mar. 22, 2004, which is incorporated by reference herein.

During chemical mechanical polishing, heaters 220 selectively heat membrane 271. For example, five or six radially spaced heaters 220 may be used to selectively heat membrane 271. Membrane 271 is in thermal communication with wafer 250, so that heat generated by heaters 220 is transferred to wafer 250. Heaters 220 may thus be used to control the chemical mechanical polishing process.

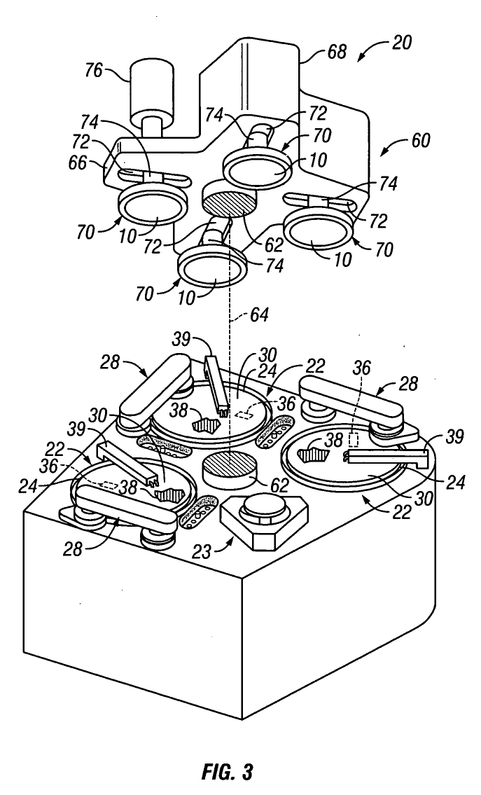

FIG. 3 shows a chemical mechanical polishing system 20 in which system 200 of FIGS. 2A to 2C may be incorporated, in some implementations. A description of a similar polishing apparatus 20 can be found in U.S. Pat. No. 5,738,574, the entire disclosure of which is incorporated herein by reference.

One or more substrates 10 can be polished by CMP apparatus 20. Polishing apparatus 20 includes a series of polishing stations 22 and a transfer station 23. Transfer station 23 transfers the substrates between the carrier heads and a loading apparatus.

Each polishing station includes a rotatable platen 24 on which is placed a polishing pad 30. The first and second stations can include a two-layer polishing pad with a hard durable outer surface or a fixed-abrasive pad with embedded abrasive particles. The final polishing station can include a relatively soft pad. Each polishing station can also include a pad conditioner apparatus 28 to maintain the condition of the polishing pad so that it will effectively polish substrates.

A rotatable multi-head carousel 60 supports four carrier heads 70. The carousel is rotated by a central post 62 about a carousel axis 64 by a carousel motor assembly (not shown) to orbit the carrier head systems and the substrates attached thereto between polishing stations 22 and transfer station 23. Three of the carrier head systems receive and hold substrates, and polish them by pressing them against the polishing pads. Meanwhile, one of the carrier head systems receives a substrate from and delivers a substrate to transfer station 23.

Each carrier head 70 is connected by a carrier drive shaft 74 to a carrier head rotation motor 76 (shown by the removal of one quarter of cover 68) so that each carrier head can independently rotate about it own axis. In addition, each carrier head 70 independently laterally oscillates in a radial slot 72 formed in carousel support plate 66. A description of a suitable carrier head 70 can be found in U.S. Pat. No. 6,422,927, filed Dec. 23, 1999, issued Jul. 23, 2002, the entire disclosure of which is incorporated by reference. In operation, the platen is rotated about its central axis 25, and the carrier head is rotated about its central axis 71 and translated laterally across the surface of the polishing pad.

A polishing liquid 38, such as a slurry containing abrasive particuls, can be supplied to the surface of polishing pad 30 by a slurry supply port or combined slurry/rinse arm 39.

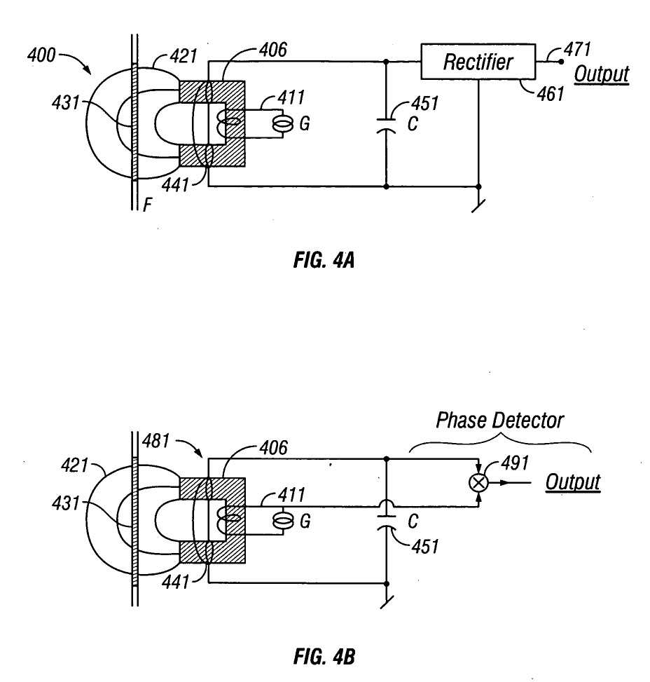

FIGS. 4A and 4B show implementations of eddy current thickness monitoring systems that may be used, in some implementations. Similar systems are described in, for example, U.S. patent application Ser. No. 09/574,008 entitled EDDY CURRENT SENSING OF METAL REMOVAL FOR CHEMICAL MECHANICAL POLISHING, filed May 19, 2000, which is hereby incorporated by reference in its entirety, and U.S. patent application Ser. No. 10/633,276, entitled EDDY CURRENT SYSTEM FOR IN-SITU PROFILE MEASUREMENT, filed Jul. 31, 2003, which is hereby incorporated by reference in its entirety.

Referring to FIG. 4A, system 400 includes a drive coil 411 for generating an oscillating magnetic field 421, which may couple with a conductive region 431 of interest (e.g., a portion of a metal layer on a semiconductor wafer). Drive coil 411 is wound around a core 406, which may be formed of a ferrite material such as a MnZn or NiZn ferrite. Core 406 may be a generally cylindrically symmetric core, or may be an elongated core.

Oscillating magnetic field 421 generates eddy currents locally in conductive region 431. The eddy currents cause conductive region 431 to act as an impedance source in parallel with a sense coil 441 and a capacitor 451. As the thickness of conductive region 431 changes, the impedance changes, resulting in a change in the Q-factor of the system. By detecting the change in the Q-factor, the eddy current sensing mechanism can sense the change in the strength of the eddy currents, and thus the change in thickness of the conductive region. Therefore, eddy current sensing systems may be used to determine parameters of the conductive region, such as a thickness of the conductive region, or may be used to determine related parameters, such as a polishing endpoint. Note that although the thickness of a particular conductive region is discussed above, the relative position of core 406 and the conductive layer may change, so that thickness information for a number of different conductive regions is obtained.

In some implementations, a change in Q-factor may be determined by measuring an eddy current amplitude as a function of time, for a fixed drive frequency and amplitude. An eddy current signal may be rectified using a rectifier 461, and the amplitude monitored via an output 471. Alternately, a change in Q-factor may be determined by measuring an eddy current phase as a function of time. FIG. 4B shows a system 481 for monitoring the phase as a function of time using a phase detector 491.

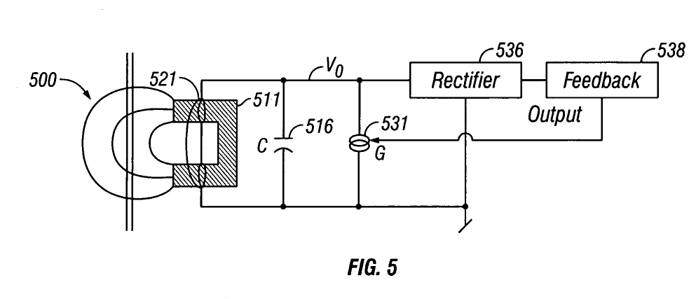

System 400 of FIGS. 4A and 4B may be used to measure the thickness of a conductive layer on a substrate. However, in some implementations, an eddy current sensing system with a higher signal to noise ratio and/or improved spatial resolution and linearity may be desired. For example, in real time process control (RTPC) applications, obtaining desired cross-wafer uniformity may require an improved eddy current sensing system. FIG. 5 shows an implementation of an eddy current sensing system 500 for improved signal to noise ratio and linearity. System 500 may be used with an elongated core, for further improvements. System 500 includes a coil 521 coupled with a core 511 (e.g., a generally cylindrically symmetric core, an elongated core, or other core). In operation, a current generator 531 (e.g., a current generator based on a marginal oscillator circuit) drives the system at the resonant frequency of an LC tank circuit formed by coil 521 (with inductance L) and a capacitor 516 (with capacitance C). A time-dependent voltage with amplitude V₀ is rectified using a rectifier 536 and provided to a feedback circuit 538. Feedback circuit 538 determines a drive current for current generator 531 to keep the amplitude of the voltage V₀ constant. For such a system, the magnitude of the drive current can be shown to be proportional to the conducting film thickness.

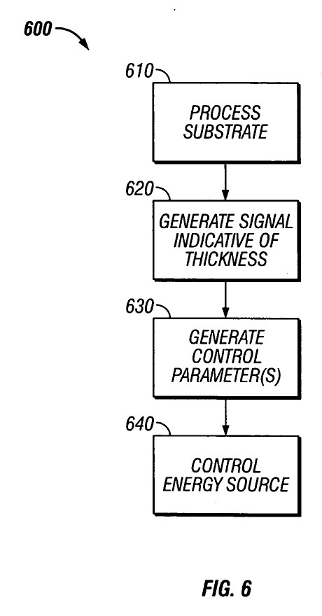

FIG. 6 shows a method 600 that may be used to improve cross-wafer uniformity in a semiconductor process, and thus help ensure that devices fabricated using the semiconductor process perform as expected. Acts of method 600 may be performed using systems and techniques described above.

At 610, substrate processing may begin. As a result of the processing, the thickness of one or more layers on the substrate may vary across the wafer. At 620, a signal indicative of the thickness of one or more layers in different regions of the wafer may be generated during processing. For example, an eddy current system may be used to generate signals indicative of the film thickness as a function of the wafer diameter. The signals may indicate the thickness of different portions of the wafer as the different portions interact with the magnetic field generated by the eddy current system.

At 630, control parameters for one or more energy sources may be generated. For example, the signals indicative of the thickness may be used in a software algorithm to generate measured thickness profile data (for example, average measured thickness data for particular radial positions of the substrate). The measured thickness profile data may be compared with reference (e.g., target) thickness profile data. Control parameters may be generated based on differences between the measured thickness profile data and the reference thickness profile data.

At 640, an energy source may be controlled based on the control parameters. For example, a radiative heater may be controlled to increase a chemical or electrochemical reaction rate in particular regions based on the control parameters. In other implementations, different types or configurations of energy sources may be used. For example, one or more resistive heaters (e.g., a resistive heater array) may be used to provide energy to selectively modify processing rates in different regions of a substrate. In another example, one or more conductive or convective heat sources may be used.

In implementations, the above described techniques and their variations may be implemented as computer software instructions. Such instructions may be stored on one or more machine-readable storage media or devices and are executed by, e.g., one or more computer processors, or cause the machine, to perform the described functions and operations.

A number of implementations have been described. Nevertheless, it will be understood that various modifications may be made without departing from the spirit and scope of the invention. For example, the current systems and techniques may be applied to semiconductor processes other than chemical mechanical polishing. For example, energy may be supplied non-uniformly across substrates undergoing etch or deposition processes, to increase thickness uniformity during those processes. Additionally, environmental factors other than thermal factors may be used to increase process uniformity. For example, light intensity may affect processing rates, and thus in some implementations a light source may thus be used in a feedback system for improving thickness uniformity. Furthermore, although the invention has been described in the context of metal polishing, it is also applicable to polishing of other layers, such as dielectrics and semiconductors. In addition, although eddy current sensors are discussed above, other types of thickness monitoring systems can be used. For example, an optical monitoring system, e.g., an interferometric system, can be used to monitor the thickness of, for example, an oxide layer.

The system may be different than outlined above. For example, some functions of controller 130 of FIG. 1 may be performed by discrete elements rather than in a single integrated controller. Similarly, system 215 of FIGS. 2A and 2B may be integrated with at least one of processor 235 and controller 230, or different functionality of the different described elements may be performed by different discrete elements, or may be integrated differently than shown. Accordingly, other implementations are within the scope of the following claims.

What is claimed is:

1. A method of chemical mechanical polishing, comprising:
polishing a substrate using a polishing apparatus;
generating one or more signals indicative of a thickness of a plurality of conductive regions of the substrate during polishing;
determining one or more control parameters for an energy source in communication with at least a portion of the polishing apparatus based on the one or more signals indicative of the thickness of the plurality of conductive regions; and
controlling the energy source based on the one or more control parameters to selectively heat the substrate during polishing.

2. The method of claim 1, wherein the energy source is a thermal radiative source.

3. The method of claim 2, wherein the one or more control parameters are one or more parameters controlling a distribution of radiative heat from the thermal radiative source.

4. The method of claim 1, wherein the energy source is in radiative communication with a first surface of a polishing pad included in the polishing apparatus.

5. The method of claim 1, wherein generating one or more signals indicative of a thickness of a plurality of conductive regions of the substrate during polishing comprises generating one or more eddy current signals.

6. The method of claim 1, wherein polishing comprises electrochemical mechanical polishing.

7. The method of claim 1, wherein determining one or more control parameters for the energy source comprises generating thickness data based on the signals indicative of a thickness of a plurality of conductive regions.

8. The method of claim 7, wherein the thickness data comprises radial thickness data indicative of a thickness parameter for a particular radial range of the substrate.

9. The method of claim 1, wherein determining one or more control parameters comprises determining the control parameters using a relationship between the substrate, a polishing pad of the polishing apparatus, and sweep motions therebetween.

10. The method of claim 1, wherein the energy source comprises a heat source, and wherein the control parameters comprise parameters to control a pulse width modulation of the heat source.

11. The method of claim 1, wherein the energy source is in radiative communication with a substrate backing system.

12. The method of claim 11, wherein the energy source is in radiative communication with a membrane of the substrate backing system.

13. A method of semiconductor processing comprising:
during processing, receiving information indicative of a thickness of a layer on a substrate and receiving information indicative of an associated location for the information indicative of the thickness on the substrate;
determining one or more control parameters for an energy source based on the information indicative of the thickness and the information indicative of an associated location; and
during processing, controlling the energy source using the control parameters to selectively heat the substrate.

14. The method of claim 13, wherein the processing comprises at least one of chemical mechanical polishing, deposition, and etch processing.

15. The method of claim 13, wherein the energy source is a heat source.

16. The method of claim 15, wherein the heat source comprises at least one of a radiative heat source and a resistive heat source.

17. The method of claim 13, wherein the energy source is a light source.

18. An article comprising one or more storage media having stored thereon instructions that when executed by one or more machines results in the following:
during processing, receiving information indicative of a thickness of a layer on a substrate;
during processing, receiving information indicative of an associated position on the substrate for the information indicative of the thickness;
determining, based on the information indicative of the thickness and the information indicative of the associated position, one or more control parameters for selective modification of one or more environmental factors proximate to the substrate; and
during processing, outputting the one or more control parameters to selectively heat the substrate.

19. The article of claim 18, wherein the one or more control parameters for selective modification of one or more environmental factors proximate to the substrate comprise one or more control parameters for an energy source to selectively modify the one or more environmental factors.

20. The article of claim 19, wherein the energy source is a thermal source, and the one or more environmental factors include the temperature.

21. The article of claim 18, wherein the processing comprises chemical mechanical processing.

22. The article of claim 21, wherein determining, based on the information indicative of the thickness and the information indicative of the associated position, the one or more control parameters comprises determining the control parameters using a relationship between a substrate, a polishing pad of the chemical mechanical processing system, and sweep motions therebetween.

23. The article of claim 22, wherein the control parameters comprise parameters to control a pulse width modulation of a heat source.

24. A semiconductor processing system comprising:
a thickness monitoring system configured to output information indicative of a local thickness of a layer on a substrate during processing;
a position monitoring system configured to output information indicative of a position of the substrate during processing; and
a processor to receive the information indicative of the local thickness and the information indicative of the position and to determine one or more control parameters based thereon, the control parameters to control an energy source configured to selectively heat the substrate, the processor further configured to output the one or more parameters.

25. The system of claim 24, further comprising an energy source to receive the one or more parameters, the energy source to selectively output energy based on the parameters.

26. The system of claim 25, wherein the energy source is a thermal source.

27. The system of claim 24, wherein the semiconductor processing system is a chemical mechanical polishing system.

28. The system of claim 24, wherein the thickness monitoring system comprises an eddy current monitoring system.

29. The system of claim 24, wherein the position monitoring system comprises at least one of an optical interrupter and an encoder.

30. The system of claim 24, wherein the position monitoring system is included in the thickness monitoring system.
